(19) United States
(12) Patent Application Publication
(10) Pub. No.: US 2015/0162518 A1
(43) Pub. Date: Jun. 11, 2015

(54) SOURCE MATERIAL SOLUTION FOR FORMING OXIDE SUPERCONDUCTOR

(71) Applicants: Genki Honda, Osaka-shi (JP); Tatsuoki Nagaishi, Osaka-shi (JP); Kei Hanafusa, Osaka-shi (JP); Iwao Yamaguchi, Tsukuba-shi (JP); Hiroaki Matsui, Tsukuba-shi (JP); Wakichi Kondo, Tsukuba-shi (JP); Toshiya Kumagai, Tsukuba-shi (JP)

(72) Inventors: Genki Honda, Osaka-shi (JP); Tatsuoki Nagaishi, Osaka-shi (JP); Kei Hanafusa, Osaka-shi (JP); Iwao Yamaguchi, Tsukuba-shi (JP); Hiroaki Matsui, Tsukuba-shi (JP); Wakichi Kondo, Tsukuba-shi (JP); Toshiya Kumagai, Tsukuba-shi (JP)

(73) Assignee: SUMITOMO ELECTRIC INDUSTRIES, LTD., Osaka-shi, Osaka (JP)

(21) Appl. No.: 14/405,287

(22) PCT Filed: Jun. 8, 2012
(86) PCT No.: PCT/JP2012/064751

§ 371 Date: Dec. 3, 2014

(51) Int. Cl. H01L 39/12

(52) U.S. Cl. CPC H01L 39/126

(57) ABSTRACT

A source material solution for forming an oxide superconductor is provided, the source material solution being used for forming on a substrate an RE 123 oxide superconductor into which flux pinning points are introduced, using a coating-pyrolysis process. Nanoparticles of a predetermined amount for forming pinning points are dispersed in the solution in which an organometallic compound is dissolved for forming the oxide superconductor. The nanoparticles have a particle size of 5 to 100 nm. The organometallic compound is an organometallic compound containing no fluorine. Accordingly, even in an FF-MOD process, the material for pins can easily be added, a treatment for thermally decomposing a metal complex and a heat treatment for generating a pin compound are unnecessary, and the particle size of the pins can suitably be controlled.

### TECHNICAL FIELD

The present invention relates to a source material solution for forming an oxide superconductor that is used when a layer made of an oxide superconductor is formed on a substrate by means of a coating-pyrolysis process.

### BACKGROUND ART

High-temperature superconducting wires aimed at application to electric power equipment such as cable, current limiter, and magnet have been and still being actively developed since the discovery of a high-temperature superconductor exhibiting superconductivity at the temperature of liquid nitrogen. Among them, an oxide superconducting thin-film wire in which a thin film layer made of an oxide superconductor (oxide superconducting layer) is formed on a substrate is currently of interest.

One of the methods for manufacturing such oxide superconducting wires is a coating-pyrolysis process (Metal Organic Deposition, abbreviated as MOD process) (Japanese Patent Laying-Open No. 2007-165153 (PTD 1)).

This process involves applying to a substrate a source material solution (MOD solution) which is manufactured by dissolving respective organometallic compounds of RE (rare earth element), Ba (barium), and Cu (copper) in a solvent, to form a coating film, thereafter performing a calcining heat treatment at around 500° C. for example to thermally decompose the organometallic compounds, removing thermally decomposed organic constituents to thereby produce a calcined film which is a precursor of an oxide superconducting thin-film, and subjecting the calcined film thus produced to a sintering heat treatment at a still higher temperature (around 750° C. to 800° C. for example) to crystallize it, thereby forming a superconducting thin layer of RE123 represented by REBa₂Cu₃O₇₋ₓ and thus manufacturing an oxide superconducting wire. This process is widely used because of its characteristics such as simpler production equipment as compared with gas phase methods by which the superconducting wire is manufactured mainly in a vacuum (such as vapor deposition, sputtering, and pulsed laser vapor deposition) and easy adaptation to a large area or a complicated shape.

Recently, however, there has been a strong demand for an oxide superconducting thin-film wire further improved in critical current density Jc and critical current Ic. In order to fulfill the demand, nano-sized flux pinning points (hereinafter referred to as “pins”) are artificially introduced for the purpose of hindering movement of nano-sized fluxons entering into an RE123 oxide superconductor in a magnetic field.

The above-described MOD process also involves adding to the source material solution an element which is to form pins, such as metal complex (salt) of Zr, to thereby form an oxide superconducting layer into which pins are introduced (NPD 1 for example).

### CITATION LIST

### Patent Document

PTD 1: Japanese Patent Laying-Open No. 2007-165153

### Non Patent Document

NPD 1: Masashi Miura et al., “Magnetic Field Angular Dependence of Critical Current in Y₁₋ₓSmₓBa₂Cu₃O_{y} Coated Conductors with Nanoparticles Derived from the TFA-MOD Process” TEION KOGAKU (J. Cryo. Soc. Jpn.) Vol. 44, No. 5 (2009), 21.0-216

### SUMMARY OF INVENTION

### Technical Problem

In the case where the above-described process is used, however, it is necessary for formation of pins to perform a treatment for thermally decomposing the added metal complex and further perform a heat treatment for generating a pin compound. In order to cause the generated pin compound to adequately perform the function of the flux pins, it is necessary to aggregate the generated pin compound so that the resultant aggregate has a certain size or more. It is not easy, however, to suitably control the particle size of the pins in such a way.

While the above process is applicable, without any problems, to a TFA-MOD process in which an organometallic compound containing fluorine is used in the source material solution, application of the above process to an FF-MOD process in which an organometallic compound containing no fluorine is used involves problems, namely it is difficult to appropriately add to the source material solution the material for a pin compound in the form of a metal complex and appropriately control formation of pins, and it is difficult to achieve oriented growth (epitaxial growth) in the step of crystal growth of the oxide superconductor.

In view of the problems above, an object of the present invention is to provide a source material solution for an MOD process that does not require a treatment for thermally decomposing a metal complex and a heat treatment for generating a pin compound and that enables the particle size of pins to suitably be controlled.

### Solution to Problem

The inventors of the present invention have conducted various experiments and studies to find that the above problems can be solved by using a source material solution to which nanoparticles are added.

Namely, in the case where a source material solution prepared by adding nanoparticles to an MOD solution is used to form an oxide superconducting layer by the MOD process, the nanoparticles adequately function as flux pins.

Since the added nanoparticles are introduced as pins, a separate treatment for thermally decomposing a metal complex and a separate heat treatment for generating a pin compound that are conventionally done are unnecessary. Further, since the particle size of the introduced pins depends on the size of the added nanoparticles, the particle size of the pins can easily, accurately, and suitably be controlled.

The present invention has been made based on the above finding. The invention according to claim 1 is a source material solution for forming an oxide superconductor, the source material solution being used for forming on a substrate an RE123 oxide superconductor into which flux pinning points are introduced, using a coating-pyrolysis process, characterized in that nanoparticles of a predetermined amount for forming the pinning points are dispersed in the solution in which an organometallic compound is dissolved for forming the oxide superconductor.

Use of the source material solution for forming an oxide superconductor according to the claim enables an oxide superconducting layer to be formed in which nanoparticles adequately functioning as flux pins are introduced under proper control as described above, and thereby enables an oxide superconducting thin-film wire having further improved Jc and Ic to be provided.

“Nanoparticles for forming pinning points” may not only be the nanoparticles functioning as flux pins by themselves, but also be nanoparticles which react with the organometallic compound contained in the source material solution during a sintering heat treatment to generate a pin compound which functions as flux pins.

The former nanoparticles may for example be nanoparticles of Ag (silver), Au (gold), Pt (platinum), BaCeO₃ (barium cerate), BaTiO₃ (barium titanate), BaZrO₃ (barium zirconate), SrTiO₃ (strontium titanate), or the like, and are not limited as long as the material does not adversely affect the superconducting characteristics of the oxide superconducting thin film.

These nanoparticles are nanoparticles which do not react with the source material solution. Therefore, pins can be introduced without performing a heat treatment separately. Moreover, the particle size of the introduced pins depends on the size of the added nanoparticles, and therefore, the particle size of the pins can easily, accurately, and suitably be controlled. Furthermore, during formation of the oxide superconductor, the composition does not vary, and therefore, an oxide superconducting thin layer with high Jc and Ic as desired can be obtained. Among the aforementioned materials, a material having a high melting point such as Pt for example is more preferable, since such a material is restrained from moving to aggregate or deforming during a calcining heat treatment and a sintering heat treatment for forming the oxide superconductor.

The latter nanoparticles may for example be nanoparticles of CeO₂ (cerium oxide), ZrO₂ (zirconium dioxide), SiC (silicon carbide), TiN (titanium nitride), or the like. These nanoparticles react with an organometallic compound contained in the source material solution to produce nanoparticles of BaCeO₃ (barium cerate), BaZrO₃ (barium zirconate), Y₂Si₂O₇, and BaTiO₃ (barium titanate), respectively, and function as flux pins.

These nanoparticles are reacted with an organometallic compound contained in the source material solution to thereby produce pins. Because of this, in contrast to the aforementioned nanoparticles that do not react with the source material solution, there is a possibility that the composition varies during formation of the oxide superconductor. It is preferable to take this possibility into consideration in preparing the source material solution in advance.

The invention according to claim 2 is the source material solution for forming an oxide superconductor according to claim 1, characterized in that the nanoparticles have a particle size of 5 to 100 nm.

If the particle size of the nanoparticles is excessively small, the nanoparticles cannot adequately function as flux pins. On the contrary, if the particle size is excessively large, the nanoparticles may adversely affect the superconducting characteristics of the oxide superconducting thin film.

A particle size of 5 to 100 nm is a size corresponding to the coherence length, which will not raise these problems.

The invention according to claim 3 is the source material solution for forming an oxide superconductor according to claim 1 or 2, characterized in that the amount of the nanoparticles added to the source material solution is 0.01 to 10 mol % relative to RE (rare earth element) in the source material solution.

If the amount of the added nanoparticles is excessively small, an adequate amount of pins cannot be formed and the nanoparticles cannot adequately function as flux pins. On the contrary, if the amount of the added nanoparticles is excessively large, an excessive amount of pins are formed, which may adversely affect the superconducting characteristics of the oxide superconducting thin film.

In the case where the amount of the added nanoparticles relative to RE in the source material solution is 0.01 to 10 mol %, these problems will not arise.

The invention according to claim 4 is the source material solution for forming an oxide superconductor according to any one of claims 1 to 3, characterized in that a dispersant is added to the source material solution.

Since the added nanoparticles may aggregate in the source material solution, the dispersant can be added to restrain the nanoparticles from aggregating, and thereby prepare the source material solution in which the nanoparticles are more uniformly dispersed.

Specific dispersants may for example be polyacrylic acid, olefin-maleic acid copolymer, polyvinylpyrrolidone, polyethyleneimine, and the like. Depending on the kind and the amount of the nanoparticles, the material and the amount of the added dispersant are appropriately determined. In the case where a commercially available nanoparticles-dispersed solution or nano-colloidal solution is used, the kind of the dispersant contained therein may not be made public, which, however, creates no problem. Preferably, these dispersants do not contain elements other than C, H, O, and N.

The invention according to claim 5 is the source material solution for forming an oxide superconductor according to any one of claims 1 to 4, characterized in that the organometallic compound is an organometallic compound containing no fluorine.

In the case where the above-described source material solution for forming an oxide superconductor is applied to the FF-MOD process, the effects of the present invention can significantly be exercised. Namely, in contrast to the case where the conventional source material solution to which a metal complex is added is used, nanoparticles can appropriately be added to the source material solution to appropriately control formation of pins, and enable crystal growth to be an adequately oriented growth.

The FF-MOD process using a source material solution of an organometallic compound containing no fluorine does not cause a dangerous gas like hydrogen fluoride gas to be generated during formation of an oxide superconducting layer, and thus requires no facilities for processing it, in contrast to the case where the TFA-MOD process is used.

### Advantageous Effects of Invention

The present invention can provide a source material solution that enables the particle size of the pins to suitably be controlled. This source material solution can be used to obtain an oxide superconducting layer into which nanoparticles which adequately function as flux pins are introduced under proper control, and provide an oxide superconducting thin-film wire having further improved Jc and Ic.

### BRIEF DESCRIPTION OF DRAWINGS

FIG. 1 is a schematic cross-sectional view of an oxide superconducting wire fabricated in Example 1.

FIG. 2 is a schematic cross-sectional view of an oxide superconducting wire fabricated in a Comparative Example.

### DESCRIPTION OF EMBODIMENTS

In the following, a description of the present invention will be given using the drawings, based on embodiments of the present invention.

### 1. Production of Source Material Solution

First, a general method for producing a source material solution of the present invention will be described. In the following, Y is used as RE.

(1) Production of MOD Solution

An MOD solution where the solvent is alcohol is synthesized from organometallic compounds of Y, Ba, and Cu at a ratio (molar ratio) of Y:Ba:Cu=1:2:3. The total cation concentration of Y³⁺, Ba²⁺, and Cu²⁺ in the MOD solution is set to 1 mol/L.

Regarding the organometallic compounds, organometallic compounds containing fluorine such as trifluoroacetate are used in the case of the TFA-MOD process, while organometallic compounds containing no fluorine such as acetylacetonate are used in the case of the FF-MOD process.

(2) Production of Nanoparticles-Dispersed Solution

Separately from the above-described production of the MOD solution, a nanoparticles-dispersed solution in which nanoparticles of a predetermined amount are dispersed in alcohol is produced. At this time, a dispersant is added in order to prevent aggregation of the nanoparticles.

(3) Production of Source Material Solution

The MOD solution and the nanoparticles-dispersed solution produced in the above-described manner are used. These solutions are mixed so that the amount of the added nanoparticles relative to Y is a predetermined mol %, to thereby produce the source material solution.

### 2. Formation of Y123 Oxide Superconducting Layer

Next, a description will be given of formation of a Y123 oxide superconducting layer using the source material solution produced in the above-described manner.

(1) Preparation of Substrate

First, a substrate on which an oxide superconducting layer is to be formed is prepared. Regarding the substrate, it is preferable to use an oriented metal substrate in which an intermediate layer having a triple layer structure made up of CeO₂/YSZ/CeO₂ formed in this order is formed on a base material such as Ni—W alloy base material, a clad-type metal base material including SUS or the like as a base metal, IBAD base material, or the like.

(2) Application of Source Material Solution

On the substrate, a predetermined amount of the source material solution is applied and thereafter dried to form a coating film of a predetermined thickness.

(3) Production of Calcined Film

The coating film is heat-treated under predetermined calcining heat treatment conditions to thereby produce a calcined film.

(4) Production of Sintered Film (Oxide Superconducting Layer)

The calcined film is heat-treated under predetermined sintering heat treatment conditions to thereby produce an oxide superconducting layer. At this time, together with the oxide superconducting layer, pins made of the nanoparticles are formed in the oxide superconducting layer.

The formed pins adequately function as flux pins in the oxide superconducting layer, and accordingly an oxide superconducting thin-film wire having improved Jc and Ic is obtained.

### EXAMPLES

In the present Example, a source material solution was produced in which Pt nanoparticles were used as nanoparticles. Further, this source material solution was used to form a Y123 oxide superconducting layer.

### Example 1

### 1. Production of Source Material Solution

(1) Production of MOD Solution

Respective acetylacetonate complexes of Y, Ba, and Cu were prepared so that the molar ratio of Y:Ba:Cu was 1:2:3, and dissolved in alcohol to produce an alcohol solution of the organometallic compounds.

(2) Pt Nanoparticles-Dispersed Solution

A platinum nanocolloidal solution (particle size: 10 nm, Pt concentration: 1 wt %, solvent: ethanol, dispersant: the dispersant does not contain elements other than C, H, O, and N) was used.

(3) Production of Source Material Solution

The produced alcohol solution of the organometallic compounds and the Pt nanoparticles-dispersed solution were mixed so that the ratio of Pt to Y (Pt/Y) was 0.06 mol %, to thereby produce a source material solution.

### 2. Formation of Oxide Superconducting Layer

(1) Coating Film Formation Step and Calcining Heat Treatment Step

The produced source material solution was applied onto a substrate in which an intermediate layer made up of three layers of Y₂O₃, YSZ, and CeO₂ was formed on a clad substrate in which a Cu layer and an Ni layer were formed on SUS, to thereby form a coating film of a predetermined thickness. After this, the coating film was raised in temperature to 500° C. in an atmospheric atmosphere and held for two hours, and thereafter cooled to form a calcined film of 300 nm in thickness as a first layer. Then, a second layer and a third layer were formed under the same conditions as the first layer, to thereby produce a calcined film of a triple layer type.

(2) Sintering Heat Treatment Step

The calcined film thus obtained was raised in temperature to 800° C. in an atmosphere of an argon/oxygen gas mixture having an oxygen concentration of 100 ppm, thereafter held for 90 minutes as it was, and lowered in temperature to 500° C. in about three hours. At this time, the atmosphere was changed to an atmosphere of 100% oxygen, and the temperature was further lowered to room temperature in five hours. Accordingly, an oxide superconducting wire of Example 1 in which a Y123 oxide superconducting layer of 0.75 pm in thickness was formed was produced.

### Comparative Example

An oxide superconducting wire of a Comparative Example was produced in a similar manner to Example 1 except that an MOD solution to which the Pt nanoparticles-dispersed solution was not added was used as the source material solution.

### 3. Evaluation of Oxide Superconducting Wires

The obtained oxide superconducting wires of Example 1 and the Comparative Example were evaluated in the following way.

(1) Cross-Sectional Structure

The S-TEM method was used to observe cross sections of the oxide superconducting layers formed in the oxide superconducting wires of Example 1 and the Comparative Example.

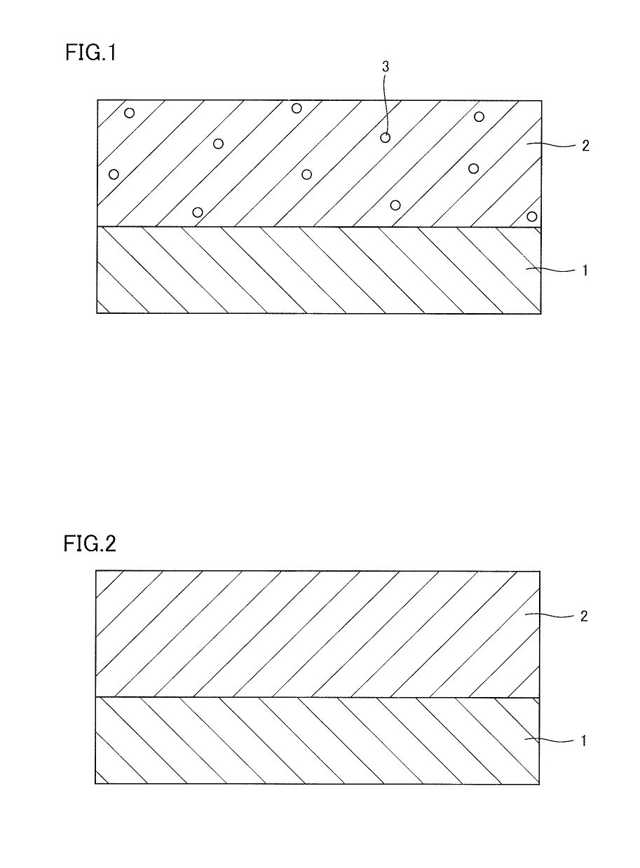

The results of the observation are schematically shown in FIGS. 1 and 2. FIGS. 1 and 2 are schematic cross-sectional views of the oxide superconducting wires produced in Example 1 and the Comparative Example, respectively. In FIGS. 1 and 2, the substrate is denoted by 1, the formed Y123 oxide superconducting layer is denoted by 2, and the Pt nanoparticles are denoted by 3.

As shown in FIG. 1, it was confirmed that Pt nanoparticles 3 were uniformly dispersed in Y123 oxide superconducting layer 2 in Example 1. In contrast, as shown in FIG. 2, formation of nanoparticles in Y123 oxide superconducting layer 2 was not observed in the Comparative Example.

(2) Measurement of Ic

The superconducting characteristics (Jc, Ic) of Example 1 and the Comparative

Example were measured at 77K in a self-magnetic field. The results of the measurement are shown in Table 1.

TABLE 1

| | addition of | formation of | Jc | Ic |
|---|---|---|---|---|
| | nanoparticles | pins | (A/cm²) | (A/cm) |
| Example 1 | added | formed | 1.4 | 103 |
| Comparative | not added | not formed | 0.8 | 63 |
| Example | | | | |

It is seen from Table 1 that use of the source material solution to which nanoparticles are added (Example 1) causes pins to be formed in the oxide superconducting layer, the pins adequately function as flux pins, and accordingly Jc and Ic are improved.

### Examples 2-4

Oxide superconducting wires of Examples 2 to 4 were produced in a similar manner to Example 1 except that Pt nanoparticles having particle sizes shown in Table 2 were used as the Pt nanoparticles.

For the oxide superconducting wires obtained in Examples 2 to 4, the superconducting characteristics (Jc, Ic) were measured in a similar manner to Example 1. The results of the measurement are shown in. Table 2 together with the results of Example 1.

### 4. Results of Evaluation

The results of the evaluation of Examples 2 to 4 are shown in Table 2 together with the results of the evaluation of Example 1.

TABLE 2

| | particle size of Pt | Jc | Ic |
|---|---|---|---|
| | nanoparticles (nm) | (A/cm²) | (A/cm) |
| Example 1 | 10 | 1.4 | 103 |
| Example 2 | 2 | 0.5 | 38 |
| Example 3 | 50 | 1.3 | 97 |
| Example 4 | 200 | 0.2 | 14 |

It is seen from Table 2 that Ic of Example 3 and Ic of Example 1 are higher than those of Example 2 and Example 4. The reason why this result is obtained is that the Pt nanoparticles in Example 3 and Example 1 have a particle size of 5 to 100 nm, which further enhances the function of the flux pinning points.

### Examples 6-9

### 1. Production of Source Material Solution

Oxide superconducting wires of Examples 5 to 8 were produced in a similar manner to Example 1 except that the ratio of Pt to Y (Pt/Y) contained in the source material solution was set to the mol% shown in Table 3.

For the oxide superconducting wires obtained in Examples S to 8, the superconducting characteristics (Jc, Ic) were measured in a similar manner to Example 1. The results of the measurement are shown in Table 3 together with the results of Example 1.

TABLE 3

| | (Pt/Y) | Jc | Ic |
|---|---|---|---|
| | mol % | (A/cm²) | (A/cm) |
| Example 5 | 0.006 | 0.9 | 67 |
| Example 6 | 0.6 | 1.2 | 86 |
| Example 7 | 6 | 1.1 | 85 |
| Example 8 | 20 | 0.6 | 45 |
| Example 1 | 0.06 | 1.4 | 103 |

It is seen from Table 3 that Ic of Example 6, Ic of Example 1, and Ic of

Example 7 are higher than those of Example 5 and Example 8. The reason why this result is obtained is that the molar ratio between Pt and Y in Example 6, Example 1, and Example 7 is 0.0:1 to 10, which further enhances the function of the flux pinning points.

Although the foregoing description is made concerning examples where Pt nanoparticles are used as the nanoparticles, it has been confirmed that nanoparticles of Ag, Au, BaCeO₃, CeO₂, SrTiO₃, ZrO₂, or the like also have the function of flux pinning like the Pt nanoparticles. As seen from the above, the present invention can form an oxide superconducting layer having a higher Ic.

While the present invention has been described based on the embodiments, the present invention is not limited to the above-described embodiments. The embodiments can be modified in a variety of ways within the scope identical and equivalent to the present invention.

### REFERENCE SIGNS LIST

1 substrate; 2 Y123 oxide superconducting layer; 3 Pt nanoparticle

1. A source material solution for forming an oxide superconductor, said source material solution being used for forming on a substrate an RE123 oxide superconductor into which flux pinning points are introduced, using a coating-pyrolysis process, characterized in that
nanoparticles of a predetermined amount for forming said pinning points are dispersed in the solution in which an organometallic compound is dissolved for forming said oxide superconductor.

2. The source material solution for forming an oxide superconductor according to claim 1, characterized in that said nanoparticles have a particle size of 5 to 100 nm.

3. The source material solution for forming an oxide superconductor according to claim 1, characterized in that the amount of said nanoparticles added to the source material solution is 0.01 to 10 mol % relative to RE (rare earth element) in the source material solution.

4. The source material solution for forming an oxide superconductor according to claim 1, characterized in that a dispersant is added to said source material solution.

5. The source material solution for forming an oxide superconductor according to claim 1, characterized in that said organometallic compound is an organometallic compound containing no fluorine.
